(19) United States
(12) Patent Application Publication
(10) Pub. No.: US 2026/0300190 A1
(43) Pub. Date: Oct. 1, 2026

(54) MEMORY CHIPLET ARCHITECTURE AND SEMICONDUCTOR PACKAGE STRUCTURE USING THE SAME

(71) Applicant: WHALECHIP CO., LTD., Taipei (TW)

(72) Inventor: Chih-Hsien LEE, Taipei (TW)

(73) Assignee: WHALECHIP CO., LTD., Taipei (TW)

(21) Appl. No.: 19/571,550

(22) Filed: Mar. 19, 2026

(30) Foreign Application Priority Data
Mar. 25, 2025 (CN) 2025103557655

(51) Int. Cl. G06F 13/16; H10B 80/00; H10W 90/00; H10W 90/10; H10D 80/30; H10W 70/60

(52) U.S. Cl. CPC G06F 13/1605; H10B 80/00; H10W 90/10; H10W 90/401; H10D 80/30; H10W 70/616; H10W 90/724

(57) ABSTRACT

Disclosed is a memory chiplet architecture including one or more memory banks. Each memory bank includes an arbiter and a memory, and the memory is addressed. The arbiter of each memory bank is configured to perform arbitration according to an incoming access command and an address space of the memory bank where it resides, to determine to access data of the memory, transmit control signals, and/or forward the incoming access command. Therefore, the number of memory banks can be adjusted according to different storage capacity requirements. Besides, the memory bank that communicates with the outside of the memory chiplet architecture is provided with an input/output interface, so that it communicates with an external chip to increase storage capacity and/or bandwidth. In addition, a memory chiplet using the memory chiplet architecture can be applied to a 3D semiconductor package structure or a 2.5D semiconductor package structure.

### CROSS REFERENCE TO RELATED PRESENT DISCLOSURE

This application claims the priority benefit of Chinese Patent Application Serial Number 2025103557655, filed on Mar. 25, 2025, the entire content of which is hereby incorporated by reference herein.

### Technical Field

The present disclosure relates to a memory chiplet architecture and a semiconductor package structure using the same, and in particular, to a memory chiplet architecture and a semiconductor package structure using the same that can meet different storage capacity requirements.

### Related Art

With the development of advanced manufacturing processes, a single semiconductor package structure can integrate various small chiplets (e.g., computing chiplets and memory chiplets) with relatively small area and relatively high manufacturing yield to improve performance and manufacturing yield.

Besides, various applications that require computing power and processing speed, such as deep neural networks and artificial intelligence (AI), have different requirements for memory capacity.

Therefore, how to provide a memory chiplet architecture that can meet different storage capacity requirements and a semiconductor packaging structure using the same is a direction that the industry is currently eager to invest in research and development.

### SUMMARY

In order to solve the above technical problem, the present disclosure provides a memory chiplet architecture that can meet different storage capacity requirements, and a memory chiplet using the memory chiplet architecture can be applied to a semiconductor package structure.

The present disclosure provides a memory chiplet architecture, which includes one or more memory banks. Each memory bank includes an arbiter and a memory, and the memory is addressed. The arbiter of each memory bank is configured to perform arbitration according to an incoming access command and an address space of the memory bank in which it resides, to determine to access data of the memory, transmit control signals, and/or forward the incoming access command.

In one embodiment of the present disclosure, each memory bank further includes a register; in each memory bank, the register is connected to the arbitrator and configured to store and override the address space of the memory bank in which it resides.

In one embodiment of the present disclosure, when the memory chiplet architecture includes the memory banks, the memory banks are configured in a two-dimensional or three-dimensional manner, and any one memory bank is operatively coupled to other memory bank(s) via its adjacent memory bank(s).

In one embodiment of the present disclosure, the adjacent memory bank(s) of the any one memory bank includes/include the memory bank located in front of, behind, to the left of, and/or to the right of the any one memory bank on the same plane, and/or the memory bank located on different planes but corresponding in position above and/or below the any one memory bank.

In one embodiment of the present disclosure, each memory bank communicates with its adjacent memory bank(s) via an interconnection/interconnections and/or with an external chip via a conductive contact/conductive contacts.

In one embodiment of the present disclosure, the memory bank that communicates with an outside of the memory chiplet architecture is provided with at least one input/output interface, so that it communicates with an external chip through the at least one input/output interface.

The present disclosure further provides a semiconductor package structure, which includes a carrier layer, a semiconductor element, and a memory chip using the memory chip architecture of the present disclosure. The semiconductor element is disposed on a surface of the carrier layer or inside the carrier layer. When the memory chip is disposed on the surface of the carrier layer or inside the carrier layer, the memory chiplet transmits signals to the semiconductor element through the carrier layer; when the memory chip is disposed on a surface of the semiconductor element opposite to the carrier layer, the memory chiplet directly transmits signals to the semiconductor element.

In one embodiment of the present disclosure, the semiconductor element is a computing chiplet or another memory chiplet.

In one embodiment of the present disclosure, the carrier layer includes a redistribution layer (RDL) and/or a package layer.

In one embodiment of the present disclosure, the carrier layer includes a semiconductor interposer layer, which is a silicon interposer layer, a bridge die layer, or a local silicon interconnect (LSI) layer.

Based on the above, in the memory chiplet architecture of the present disclosure, by including an arbitrator in the memory bank, the storage capacity of the memory chiplet architecture can be increased as the number of memory banks increases, thereby meeting different storage capacity requirements. In addition, since the memory banks may communicate with its adjacent memory bank(s) via the interconnect(s) and/or with the external chip via the conductive contact(s), or the memory chiplet architecture may communicate with the external chip through at least one input/output interface provided by the memory bank, the storage capacity and/or bandwidth may be increased. Furthermore, the memory chip using the memory chiplet architecture of the present disclosure can be applied to a 3D semiconductor package structure or a 2.5D semiconductor package structure (i.e., the semiconductor package structure of the present disclosure).

It should be understood, however, that this summary may not contain all aspects and embodiments of the present disclosure, that this summary is not meant to be limiting or restrictive in any manner, and that the disclosure as disclosed herein will be understood by one of ordinary skill in the art to encompass obvious improvements and modifications thereto.

### BRIEF DESCRIPTION OF THE DRAWINGS

The features of the exemplary embodiments believed to be novel and the elements and/or the steps characteristic of the exemplary embodiments are set forth with particularity in the appended claims. The Figures are for illustration purposes only and are not drawn to scale. The exemplary embodiments, both as to organization and method of operation, may best be understood by reference to the detailed description which follows taken in conjunction with the accompanying drawings in which:

FIG. 1 is a schematic diagram of a first embodiment of a semiconductor package structure using a memory chiplet architecture of the present disclosure.

FIG. 2 is a schematic diagram of a second embodiment of a semiconductor package structure using a memory chiplet architecture of the present disclosure.

FIG. 3 is a schematic diagram of a third embodiment of a semiconductor package structure using a memory chiplet architecture of the present disclosure.

FIG. 4 is a schematic diagram of an embodiment of the memory chiplet architecture of FIG. 1.

FIG. 5 is a schematic diagram of another embodiment of the memory chiplet architecture of FIG. 1.

FIG. 6 is a schematic diagram of yet another embodiment of the memory chiplet architecture of FIG. 1.

### DETAILED DESCRIPTION OF THE EMBODIMENTS

The embodiments of the present invention will be described below with reference to the accompanying drawings. Directional terms, such as “up,” “down,” “left,” “right,” “front,” “back,” and the like, used in the following embodiments are merely directions with reference to the accompanying drawings. Therefore, the directional terms used herein are for illustration, and are not intended to limit the present invention. Further, in these figures, the same reference numerals are used to refer to the same or similar components/method flows.

It must be understood that the words “including”, “comprising” and the like used in this specification are used to indicate the existence of specific technical features, values, method steps, work processes, elements and/or components. However, it does not exclude that more technical features, values, method steps, work processes, elements, components, or any combination of the above can be added.

It must be understood that when an element is described as being “connected” or “coupled” to another element, it may be directly connected or coupled to another element, and intermediate elements therebetween may be present. In contrast, when an element is described as “directly connected” or “directly coupled” to another element, there is no intervening element therebetween. Additionally, it is understood that the term “and/or” may be used herein for including any or all combinations of one or more of the associated listed items

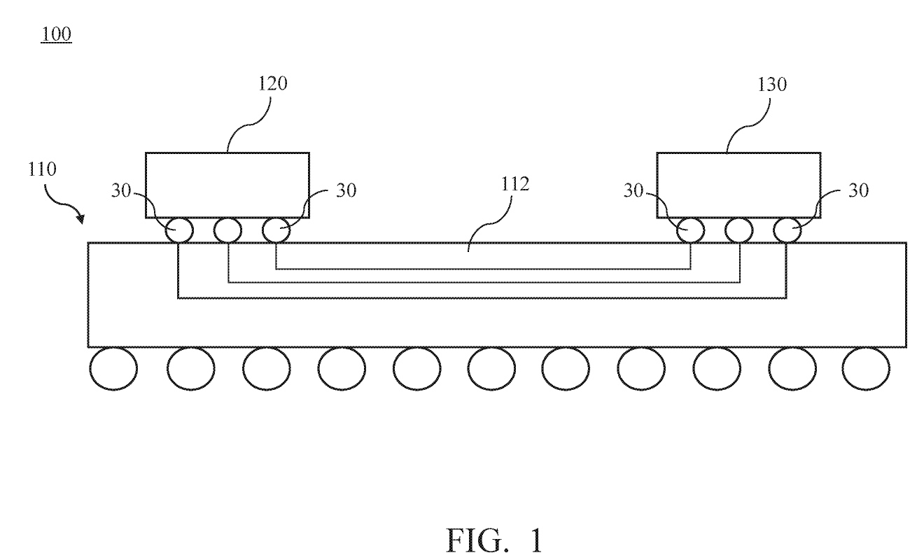

Please refer to FIG. 1, which is a schematic diagram of a first embodiment of a semiconductor package structure using a memory chiplet architecture of the present disclosure. As shown in FIG. 1, a semiconductor package structure 100 includes a carrier layer 110, a semiconductor element 120, and a memory chiplet using a memory chiplet architecture 130. The carrier layer 110 includes a semiconductor interposer layer 112, which may be, but is not limited to, a silicon interposer layer, a bridge die layer, or a local silicon interconnect (LSI) layer. The semiconductor element 120 may be, but is not limited to, a computing chiplet (e.g., a system on a chip (SoC)) or another memory chiplet using the memory chiplet architecture 130.

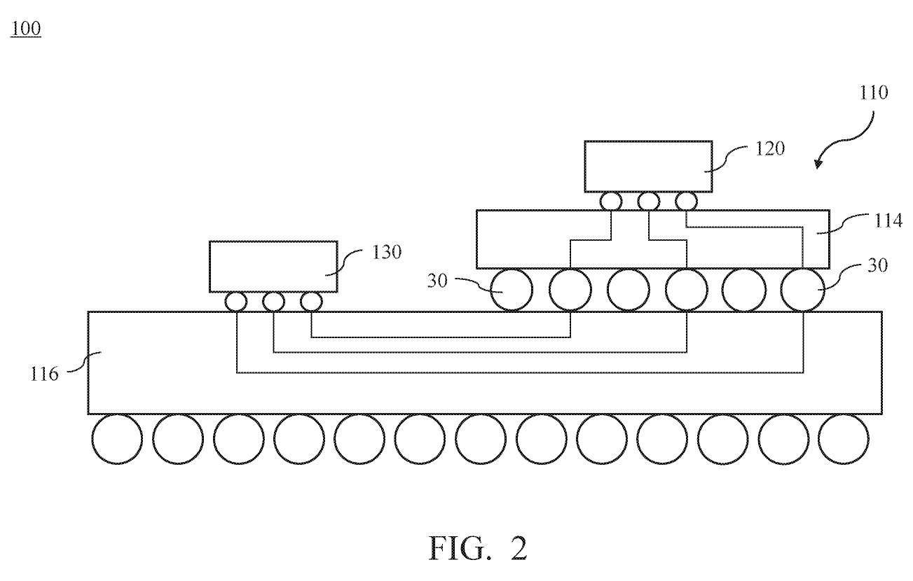

In this embodiment, the semiconductor element 120 and the memory chiplet using the memory chiplet architecture 130 are disposed on the surface of the carrier layer 110. The memory chiplet using the memory chiplet architecture 130 transmit signals to the semiconductor element 120 through the semiconductor interposer layer 112 of the carrier layer 110. The semiconductor element 120 and the memory chip using the memory chiplet architecture 130 may be electrically connected to the semiconductor interposer layer 112 using a plurality of conductive contacts 30, but this embodiment is not intended to limit the present disclosure. In one embodiment, please refer to FIG. 2, which is a schematic diagram of a second embodiment of a semiconductor package structure using a memory chiplet architecture of the present disclosure. The carrier layer 110 may include a redistribution layer 114 and a package layer 116. The redistribution layer 114 is disposed on the package layer 116 and is electrically connected to the package layer 116 by a plurality of conductive contacts 30. The semiconductor element 120 is disposed on the surface of the redistribution layer 114 (i.e., the semiconductor element 120 is disposed on the surface of the carrier layer 110). The memory chiplet using the memory chiplet architecture 130 is disposed on the surface of the package layer 116 (i.e., the memory chiplet using the memory chiplet architecture 130 is disposed inside the carrier layer 110). The memory chiplet using the memory chiplet architecture 130 transmits signals to the semiconductor element 120 through the redistribution layer 114 and the package layer 116 of the carrier layer 110. Besides, since the carrier layer 110 may include a redistribution layer 114 and a package layer 116, the semiconductor element 120 and the memory chiplet using the memory chiplet architecture 130 may be selectively disposed on the surface of the redistribution layer 114 or the package layer 116 (i.e., the semiconductor element 120 and the memory chiplet using the memory chiplet architecture 130 may be disposed on the surface of the carrier layer 110 or inside the carrier layer 110).

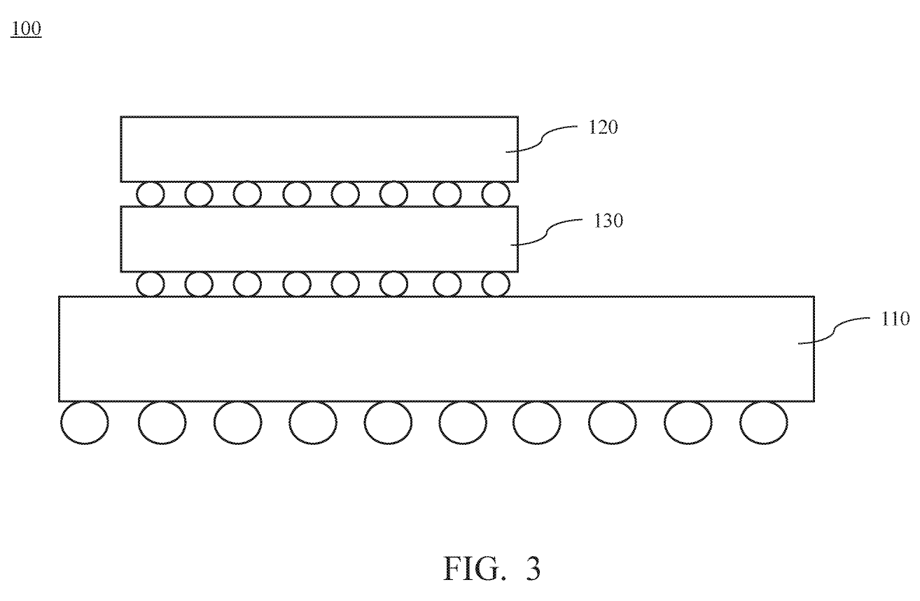

In another embodiment, please refer to FIG. 3, which is a schematic diagram of a third embodiment of a semiconductor package structure using a memory chiplet architecture of the present disclosure. The memory chiplet using the memory chiplet architecture 130 is disposed on the surface of the carrier layer 110, and the semiconductor element 120 is disposed on the surface of the memory chiplet using the memory chiplet architecture 130 opposite to the carrier layer 110 (i.e., the semiconductor element 120 is stacked on the memory chiplet using the memory chiplet architecture 130). The memory chiplet using the memory chiplet architecture 130 directly transmits signals to the semiconductor element 120.

As shown in FIGS. 1 to 3, the memory chiplet using the memory chiplet architecture 130 may be applied to a 3D semiconductor package structure or a 2.5D semiconductor package structure (i.e., semiconductor package structure 100). In addition, when the semiconductor element 120 is another memory chiplet using the memory chiplet architecture 130, it may be considered as expanding the storage capacity of the semiconductor package structure 100. Furthermore, the number and the configuration of the semiconductor element 120 and the memory chipslet using the memory chiplet architecture 130 included in the semiconductor package structure 100 may be adjusted according to actual needs.

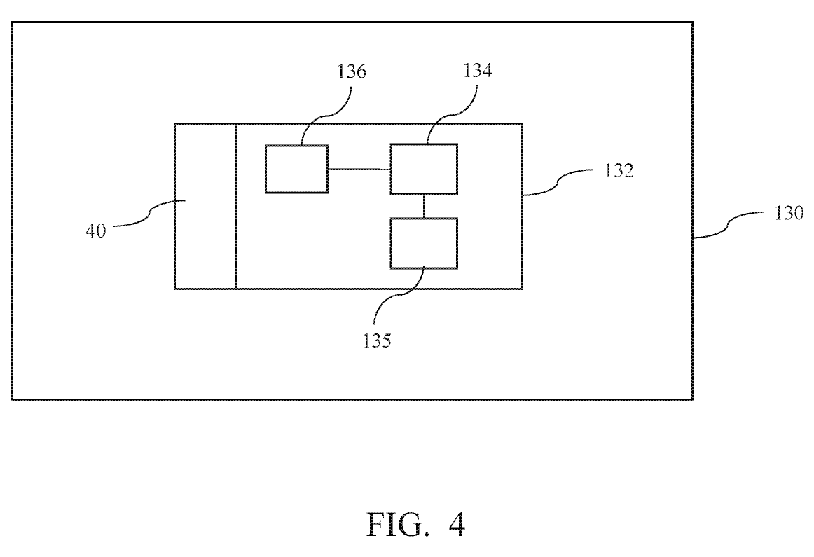

Please refer to FIG. 4, which is a schematic diagram of an embodiment of the memory chiplet architecture of FIG. 1. As shown in FIG. 4, the memory chiplet architecture 130 may include a single memory bank 132. The memory bank 132 includes an arbiter 134 and a memory 135. The memory 135 can be addressed. The arbiter 134 is configured to perform arbitration according to an incoming access command, and an address space of the memory bank 132 in which it resides, to determine to access data of the memory 135, transmit control signals, and/or forward the incoming access command. Specifically, the arbitrator 134 of the memory bank 132 determines whether the target address included in the incoming access command falls within the address space of the memory bank 132 in which it resides. If so, the arbitrator 134 of the memory bank 132 returns the data stored in the memory 135 or writes the data included in the incoming access command into the memory 135 according to the type of the incoming access command (e.g., the read command or the write command), and selectively returns a control signal indicating that the data write is complete. If not, the arbitrator 134 of the memory bank 132 forwards the incoming access command via the carrier layer 110 to another memory chiplet using the memory chiplet architecture 130 (e.g., the semiconductor element 120 as shown in FIG. 1). The incoming access command may originate from outside the semiconductor package structure 100 or from a computing chiplet as the semiconductor element 120, but is not limited thereto. At least one side of the memory bank 132 communicating with the outside of the memory chiplet architecture 130 may be provided with an input/output interface 40 (i.e., the memory bank 132 may be provided with at least one input/output interface 40) to communicate with the semiconductor element 120. Besides, the number and configuration locations of the input/output interfaces 40 of the memory bank 132 may be adjusted according to actual needs.

In one embodiment, the memory bank 132 further includes a register 136, which is connected to the arbitrator 134 and configured to store or override the address space of the memory bank 132 in which it resides.

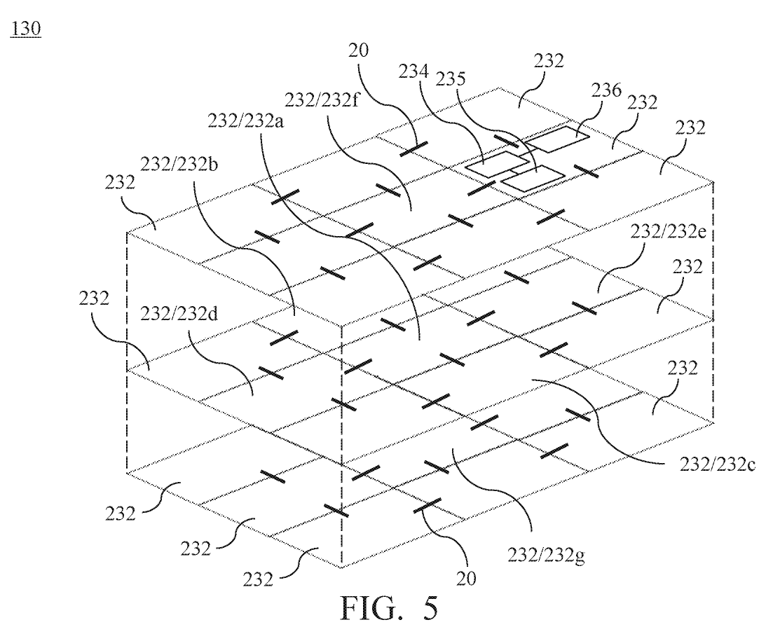

Please refer to FIG. 5, which is a schematic diagram of another embodiment of the memory chiplet architecture of FIG. 1. As shown in FIG. 5, the memory chiplet architecture 130 may include a plurality of memory banks 232 (e.g., a 3-layer memory bank array, with each layer including 9 memory banks 232, for a total of 27 memory banks 232). Each memory bank 232 includes an arbitrator 234 and a memory 235, and the memory 235 is addressed. Each memory bank 232 has an address space. The storage capacity of the memory 235 in each memory bank 232 may be, but is not limited to, 4 megabyte (MB) (i.e., the storage capacity of the memory chiplet architecture 130 is 108 MB). It should be noted that, to avoid complexity in the figures, only a single arbitrator 234 and a single memory 235 are shown in FIG. 5, and the other arbitrators 234 and memories 235 are omitted.

In this embodiment, the plurality of memory banks 232 are configured in a three-dimensional manner (for example, 27 memory banks 232 are arranged in a 3×3×3 configuration). Any one memory bank 232 may communicate with its adjacent memory bank(s) 232 via interconnect(s) 20 (as shown by the thick lines in the figure). Any one memory bank 232 may be operatively coupled to other memory bank(s) 232. Any one memory bank 232 may be coupled to its adjacent memory bank(s) 232, which may include the memory bank 232 located in front of, behind, to the left of, and/or to the right of the any one memory bank 232 on the same plane, and/or the memory bank 232 located on different planes but corresponding in position above and/or below the any one memory bank 232. For example, the memory bank 232a is adjacent to the memory bank 232b (i.e., the memory bank 232 located in front of the any one memory bank 232/ the memory bank 232a on the same plane), the memory bank 232c (i.e., the memory bank 232 located behind the any one memory bank 232/ the memory bank 232a on the same plane), the memory bank 232d (i.e., the memory bank 232 located on the left side of the any one memory bank 232/ the memory bank 232a on the same plane), the memory bank 232e (i.e., the memory bank 232 located on the right side of the any one memory bank 232/ the memory bank 232a on the same plane), the memory bank 232f (i.e., the memory bank 232 located on different planes but corresponding in position above the any one memory bank 232/ the memory bank 232a), and the memory bank 232g (i.e., the memory bank 232 located on different planes but corresponding in position below the any one memory bank 232/ the memory bank 232a), but is not limited thereto. It should be noted that, to avoid complexity in the figures, the interconnections between the memory banks 232 on different planes but in corresponding positions are omitted in FIG. 5. In addition, any one memory bank 232 may further communicate with an external chip (e.g., the semiconductor element 120 in FIG. 1) via conductive contacts (e.g., the conductive contacts 30 in FIG. 1). Because the memory bank 232 may communicate with its adjacent memory bank(s) 232 via the interconnect(s) 20 and/or with the external chip via the conductive contact(s), the storage capacity and/or bandwidth may be increased.

In another embodiment, the plurality of memory banks 232 are configured in a two-dimensional manner. Each memory bank 232 may communicate with its adjacent memory bank(s) 232 via interconnect(s) 20. Each memory bank 232 is operatively coupled to other memory bank(s) 232 via its adjacent memory bank(s) 232. The adjacent memory bank(s) 232 of the any one memory bank 232 may include the memory bank 232 located in front of, behind, to the left of, and/or to the right of the any one memory bank 232 on the same plane. Additionally, any one memory bank 232 may further communicate with the external chip (e.g., the semiconductor element 120 of FIG. 1) via conductive contacts (e.g., the conductive contacts 30 of FIG. 1). Since the memory bank 232 may communicate with its adjacent memory bank(s) 232 via the interconnect(s) 20 and/or with the external chip via the conductive contact(s), the storage capacity and/or bandwidth may be increased.

Referring to FIG. 5, the arbitrator 234 of each memory bank 232 is configured to a perform arbitration according to an incoming access command, and an address space of the memory bank 232 in which it resides, to determine to access data of the memory 235, transmit control signals, and/or forward the incoming access command. Specifically, the arbitrator 234 of the memory bank 232 determines whether the target address included in the incoming access command falls within the address space of the memory bank 232 in which it resides. If so, when the incoming access command is a read command, the data stored in the memory 235 is transferred to the element (e.g., the outside of the semiconductor package structure 100 or the computing chiplet as the semiconductor element 120) that sent the incoming access command to the memory chiplet architecture 130 according to the transmission path of the incoming access command, the shortest transmission path, or the preset transmission path; when the incoming access command is a write command, the data included in the incoming access command is written (stored) into the memory 235 and selectively transmits a control signal indicating that the data write is complete to the element that sent the incoming access command to the memory chiplet architecture 130 according to the transmission path of the incoming access command, the shortest transmission path, or the preset transmission path. If not (i.e., the arbitrator 234 of memory bank 232 determines that the target address included in the incoming access command does not fall within the address space of the memory bank 232 in which it resides), the incoming access command is forwarded to an adjacent memory bank 232 (the adjacent memory bank 232 may be, but is not limited to, the memory bank 232 located in front of, behind, to the left of, or to the right of the memory bank 232 on the same plane, or the memory bank 232 located on different planes but corresponding in position above or below the memory bank 232; i.e., the forwarding direction of the incoming access command is not specified), or the incoming access command is forwarded to another memory chiplet using the memory chiplet architecture 130 (e.g., the semiconductor element 120 in FIG. 1) via the carrier layer 110.

It should be noted that when the memory chiplet using the memory chiplet architecture 130 of FIG. 5 is applied to the semiconductor package structure 100 of FIG. 3, and the arbitrator 234 of the memory bank 232 determines that the target address included in the incoming access command does not fall within the address space of the memory bank 232 in which it resides, the memory bank 232 directly forwards the incoming access command to another memory chiplet using the memory chiplet architecture 130 (i.e., the memory bank 232 does not need to forward the incoming access command to another memory chiplet using the memory chiplet architecture 130 via the carrier layer 110). The process executed by the memory bank 232 in the another memory chiplet using the memory chiplet architecture 130 according to the incoming access command is the same as that described above, and will not be repeated here. The memory bank 232 of the another memory chiplet using the memory chiplet architecture 130 may be considered as extended memory banks 232.

In one embodiment, before each incoming access command is forwarded, the address of the address space of the current memory bank 232 is added. Therefore, the incoming access command may record its forwarding path, so that the data of the target address and the control signal indicating that the data write is complete may be transmitted in reverse to the element that sent the incoming access command to the memory chiplet using the memory chiplet architecture 130 according to the transmission path of the incoming access command.

In another embodiment, each memory bank 232 may store an address table including the address spaces of all memory banks 232 in the memory chiplet architecture 130. Therefore, the data of the target address and the control signal indicating that the data write is complete may be transmitted to the element that sent the incoming access command to the memory chiplet using the memory chiplet architecture 130 through the shortest transmission path according to the address table.

In yet another embodiment, each memory bank 232 has a fixed direction for transmitting data and control signals. Therefore, the data of the target address and the control signal indicating that the data write is complete may be transmitted to the element that sent the incoming access command to the memory chiplet using the memory chiplet architecture 130 according to a preset transmission path.

In still another embodiment, each memory bank 232 may record the directions of receiving and forwarding the incoming access command. Therefore, each memory bank 232 may transmit the data transferred by the memory bank 232 with the target address and the control signal indicating that the data write is complete in reverse according to the direction of receiving the incoming access command, so that the data of the target address and the control signal indicating that the data write is complete may be transmitted in reverse to the element that sent the incoming access command to the memory chiplet using the memory chiplet architecture 130 according to the transmission path of the incoming access command.

In one embodiment, each memory bank 232 may further include a register 236. In each memory bank 232, the register 236 is connected to the arbitrator 234 and is configured to store or override the address space of the memory bank 232 in which it resides. It should be noted that, to avoid complexity in the drawings, only a single register 236 is shown in FIG. 5, and the other registers 236 are omitted.

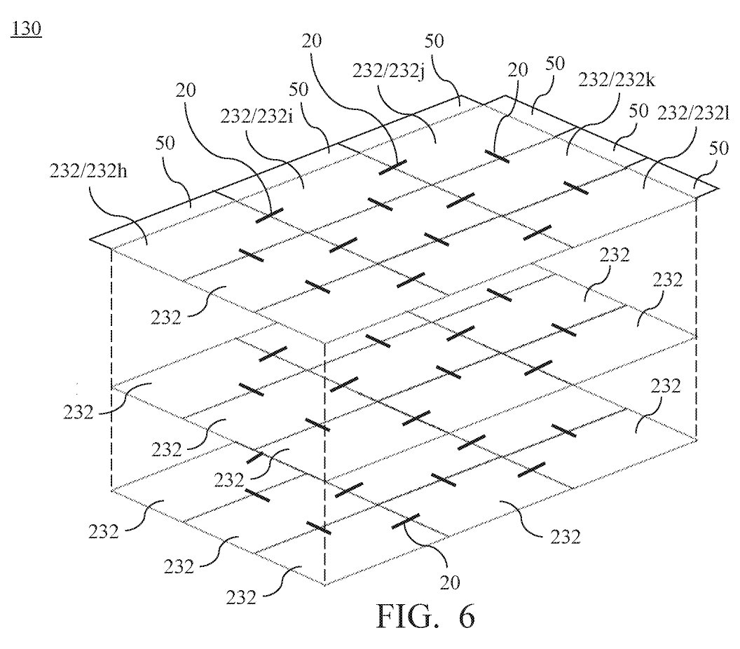

In one embodiment, please refer to FIG. 6, which is a schematic diagram of yet another embodiment of the memory chiplet architecture of FIG. 1. Each of the memory banks 232 (e.g., the memory banks 232h, 232i, 232j, 232k, and 232l) in the memory chiplet architecture 130 that communicates with the outside of the memory chiplet architecture 130 is provided with at least one input/output interface 50, so that the memory chiplet architecture 130 may communicate with the external chip(s) through the at least one input/output interface 50. The memory chiplet architecture 130 may communicate with other memory chiplet architectures 130 (i.e., another memory chiplet using the memory chiplet architecture 130) through the at least one input/output interface 50, so that the memory banks 232 of another memory chiplet using the memory chiplet architecture 130 may be regarded as expanded memory banks 232. Therefore, the memory chiplet architecture 130 may simultaneously improve the storage capacity and bandwidth through the configuration of the input/output interfaces 50. Furthermore, the number and configuration locations of the input/output interfaces 50 provided by a single memory bank 232 communicating with the outside of the memory chiplet architecture 130 may be adjusted according to actual needs. Therefore, the arbitrator 234 of each memory bank 232 communicating with the outside of the memory chiplet architecture 130 may be further configured to forward the incoming access command to the external component of the memory chiplet architecture 130 (e.g., the external component of the semiconductor package structure 100, a computing chiplet as the semiconductor element 120, or another memory chiplet using the memory chiplet architecture 130) via the input/output interface 50.

In summary, in the memory chiplet architecture of the present disclosure, by including an arbitrator in the memory bank the storage capacity of the memory chiplet architecture can be increased as the number of memory banks increases, thereby meeting different storage capacity requirements. In addition, the memory banks in the memory chiplet architecture of the present disclosure may be configured in a two-dimensional or three-dimensional manner, each memory bank may communicate with its adjacent memory bank(s) (i.e., the memory bank located in front of, behind, to the left of, and/or to the right of the current memory bank, and/or the memory bank located on different planes but corresponding in position above and/or below the current memory bank) through the setting of the arbiter, which enables the memory chiplet architecture to perform corresponding operations according to the incoming access command. Besides, the memory chiplet architecture of the present disclosure may be provided with at least one input/output interface through the memory bank(s) that communicate with the outside of the memory chiplet architecture, so that the memory chiplet using the memory chiplet architecture may communicate with the external chip(s), thereby improving the storage capacity and/or bandwidth. Additionally, since the memory bank(s) may communicate with the adjacent memory bank(s) through the interconnection(s) and/or with the external chip(s) through the conductive contact(s), the storage capacity and/or bandwidth may be increased. Moreover, the memory chiplet architecture of the present disclosure may be applied to a 3D semiconductor package structure or a 2.5D semiconductor package structure (i.e., the semiconductor package structure of the present disclosure). Furthermore, in the semiconductor package structure of the present disclosure, the number of memory chiplet architectures may be multiple to expand the storage capacity and bandwidth of the semiconductor package structure.

Although the present disclosure has been explained in relation to its preferred embodiment, it does not intend to limit the present disclosure. It will be apparent to those skilled in the art having regard to this present disclosure that other modifications of the exemplary embodiments beyond those embodiments specifically described here may be made without departing from the spirit of the disclosure. Accordingly, such modifications are considered within the scope of the disclosure as limited solely by the appended claims.

What is claimed is:

1. A memory chiplet architecture, comprising:
one or more memory banks, each memory bank including an arbitrator and a memory, wherein the memory is addressed;
wherein the arbitrator of each memory bank is configured to perform arbitration according to an incoming access command and an address space of the memory bank in which it resides, to determine to access data of the memory, transmit control signals and/or forward the incoming access command.

2. The memory chiplet architecture according to claim 1, wherein each memory bank further comprises a register; in each memory bank, the register is connected to the arbitrator and is configured to store and override the address space of the memory bank in which it resides.

3. The memory chiplet architecture according to claim 1, wherein when the memory chiplet architecture comprises the memory banks, the memory banks are configured in a two-dimensional or three-dimensional manner, and any one memory bank is operatively coupled to other memory bank(s) via its adjacent memory bank(s).

4. The memory chiplet architecture according to claim 3, wherein the adjacent memory bank(s) of the any one memory bank comprises/comprise the memory bank located in front of, behind, to the left of, and/or to the right of the any one memory bank on the same plane, and/or the memory bank located on different planes but corresponding in position above and/or below the any one memory bank.

5. The memory chiplet architecture according to claim 3, wherein each memory bank communicates with its adjacent memory bank(s) via an interconnection/interconnections and/or with an external chip via a conductive contact/conductive contacts.

6. The memory chiplet architecture according to claim 1, wherein the memory bank that communicates with an outside of the memory chiplet architecture is provided with at least one input/output interface, so that it communicates with an external chip through the at least one input/output interface.

7. A semiconductor package structure, comprising:
a carrier layer;
a memory chiplet using the memory chiplet architecture according to claim 1, disposed on a surface of the carrier layer or inside the carrier layer; and
a semiconductor element;
wherein when the semiconductor element is disposed on the surface of the carrier layer or inside the carrier layer, the memory chiplet transmits signals to the semiconductor element through the carrier layer; when the semiconductor element is disposed on a surface of the memory chiplet opposite to the carrier layer, the memory chiplet directly transmits signals to the semiconductor element.

8. The semiconductor package structure according to claim 7, wherein the semiconductor element is a computing chiplet or another memory chiplet.

9. The semiconductor package structure according to claim 7, wherein the carrier layer comprises a redistribution layer (RDL) and/or a package layer.

10. The semiconductor package structure according to claim 7, wherein the carrier layer comprises a semiconductor interposer layer, which is a silicon interposer layer, a bridge die layer, or a local silicon interconnect (LSI) layer.
